(19) United States
(12) Patent Application Publication
(10) Pub. No.: US 2026/0262225 A1
(43) Pub. Date: Sep. 3, 2026

(54) VIA CAPACITORS AND METHODS FOR FORMING THE SAME

(71) Applicant: Sandisk Technologies, Inc., Milpitas, CA (US)

(72) Inventors: Kiyokazu SHISHIDO, Yokkaichi (JP); Hiroshi NAKATSUJI, Yokkaichi (JP); Jun AKAIWA, Yokkaichi (JP); Kosuke TANAKA, Yokkaichi (JP); Hiroki YABE, Yokkaichi (JP)

(21) Appl. No.: 19/068,674

(22) Filed: Mar. 3, 2025

(51) Int. Cl. H10B 43/40; H01L 23/522; H10B 43/27

(52) U.S. Cl. CPC H10B 43/40; H10B 43/27; H10W 20/496

(57) ABSTRACT

A semiconductor structure includes a shallow trench isolation structure embedded in a semiconductor substrate, and a via capacitor located over the shallow trench isolation structure.

### FIELD

The present disclosure relates generally to the field of semiconductor devices, and particularly to a semiconductor structure including via capacitors and methods for forming the same.

### BACKGROUND

Capacitors in semiconductor circuits provide various circuit functions by storing charge, smoothing out voltage fluctuations, reducing unwanted electrical noise, and maintaining stable signals.

### SUMMARY

According to an aspect of the present disclosure, a semiconductor structure comprises: a shallow trench isolation structure comprising a lower portion embedded in an upper portion of a semiconductor substrate and further comprising an upper portion protruding above a horizontal plane including a top surface of the semiconductor substrate; a conductive plate located on a top surface of the shallow trench isolation structure; a contact-level dielectric layer overlying the semiconductor substrate and the conductive plate; a capacitor via trench vertically extending through the contact-level dielectric layer; and a via capacitor located in the capacitor via trench and comprising an outer electrode, a capacitor dielectric, and an inner electrode, wherein the outer electrode comprises a horizontally-extending bottom conductive plate portion contacting the conductive plate, and a tubular vertically-extending conductive portion having outer sidewall segments that contact the contact-level dielectric layer.

According to another aspect of the present disclosure, a semiconductor structure comprises: a shallow trench isolation structure comprising a lower portion embedded in an upper portion of a semiconductor substrate and further comprising an upper portion protruding above a horizontal plane including a top surface of the semiconductor substrate; field effect transistors of a sense amplifier circuit located on the semiconductor substrate, wherein the shallow trench isolation structure is located in a gap between the field effect transistors; a contact-level dielectric layer overlying the field effect transistors and the shallow trench isolation structure; a capacitor via trench vertically extending through the contact-level dielectric layer over or into the shallow trench isolation structure; and a via capacitor located in the capacitor via trench and comprising an outer electrode, a capacitor dielectric, and an inner electrode, wherein one of the inner electrode and the outer electrode is electrically connected to a sense amplifier bus which electrically connects the field effect transistors to a sense amplifier input node.

According to yet another aspect of the present disclosure, a method of forming a semiconductor structure comprises: forming a shallow trench isolation structure in a semiconductor substrate; forming field effect transistors on portions of the semiconductor substrate that are not covered by the shallow trench isolation structure; forming a contact-level dielectric layer over the semiconductor substrate and the field effect transistors; forming a capacitor via trench at least through the contact-level dielectric layer; and forming a via capacitor in the capacitor via trench, wherein the via capacitor comprises an outer electrode, a capacitor dielectric, and an inner electrode, wherein the outer electrode comprises a horizontally-extending bottom conductive plate portion contacting the conductive plate, and a tubular vertically-extending conductive portion having outer sidewall segments that contact the contact-level dielectric layer.

### BRIEF DESCRIPTION OF THE DRAWINGS

FIG. 1A is a vertical cross-sectional view of a first exemplary structure after formation of a gate dielectric layer and a gate electrode material layer over a semiconductor substrate according to a first embodiment of the present disclosure. FIG. 1B is a top-down view of the first exemplary structure of FIG. 1A. The vertical plane A-A′ is the cut plane of the vertical cross-sectional view of FIG. 1A.

FIG. 2A is a vertical cross-sectional view of the first exemplary structure after formation of a shallow trench isolation structure according to a first embodiment of the present disclosure. FIG. 2B is a top-down view of the first exemplary structure of FIG. 2A. The vertical plane A-A′ is the cut plane of the vertical cross-sectional view of FIG. 2A.

FIG. 3A is a vertical cross-sectional view of the first exemplary structure after formation of upper gate electrode portions and a conductive plate according to the first embodiment of the present disclosure. FIG. 3B is a top-down view of the first exemplary structure of FIG. 3A. The vertical plane A-A′ is the cut plane of the vertical cross-sectional view of FIG. 3A.

FIG. 4A is a vertical cross-sectional view of the first exemplary structure after formation of lower gate electrode portions and gate dielectrics according to the first embodiment of the present disclosure. FIG. 4B is a top-down view of the first exemplary structure of FIG. 4A. The vertical plane A-A′ is the cut plane of the vertical cross-sectional view of FIG. 4A.

FIG. 5A is a vertical cross-sectional view of the first exemplary structure after formation of a contact-level dielectric layer according to the first embodiment of the present disclosure. FIG. 5B is a top-down view of the first exemplary structure of FIG. 5A. The vertical plane A-A′ is the cut plane of the vertical cross-sectional view of FIG. 5A.

FIG. 6A is a vertical cross-sectional view of the first exemplary structure after formation of contact via cavities and capacitor via trenches according to the first embodiment of the present disclosure. FIG. 6B is a top-down view of the first exemplary structure of FIG. 6A. The vertical plane A-A′ is the cut plane of the vertical cross-sectional view of FIG. 6A.

FIG. 7A is a vertical cross-sectional view of the first exemplary structure after formation of an outer electrode material layer and a capacitor dielectric material layer according to the first embodiment of the present disclosure. FIG. 7B is a top-down view of the first exemplary structure of FIG. 7A. The vertical plane A-A′ is the cut plane of the vertical cross-sectional view of FIG. 7A.

FIG. 8A is a vertical cross-sectional view of the first exemplary structure after patterning the capacitor dielectric material layer according to the first embodiment of the present disclosure. FIG. 8B is a top-down view of the first exemplary structure of FIG. 8A. The vertical plane A-A′ is the cut plane of the vertical cross-sectional view of FIG. 8A.

FIG. 9A is a vertical cross-sectional view of the first exemplary structure after deposition of an inner electrode material layer according to the first embodiment of the present disclosure. FIG. 9B is a top-down view of the first exemplary structure of FIG. 9A. The vertical plane A-A′ is the cut plane of the vertical cross-sectional view of FIG. 9A.

FIG. 10A is a vertical cross-sectional view of the first exemplary structure after patterning the inner electrode material layer, the capacitor dielectric material layer, and the outer electrode material layer according to the first embodiment of the present disclosure. FIG. 10B is a top-down view of the first exemplary structure of FIG. 10A. The vertical plane A-A′ is the cut plane of the vertical cross-sectional view of FIG. 10A.

FIG. 11A is a vertical cross-sectional view of the first exemplary structure after formation of an interconnect-level dielectric layer and metal interconnect structures according to the first embodiment of the present disclosure. FIG. 11B is a top-down view of the first exemplary structure of FIG. 11A. The vertical plane A-A′ is the cut plane of the vertical cross-sectional view of FIG. 11A.

FIG. 12A is a vertical cross-sectional view of a second exemplary structure after formation of a shallow trench isolation structure, semiconductor devices, a contact-level dielectric layer, and contact-level metal interconnect structures according to a second embodiment of the present disclosure. FIG. 12B is a top-down view of the second exemplary structure of FIG. 12A. The vertical plane A-A′ is the cut plane of the vertical cross-sectional view of FIG. 12A.

FIG. 13A is a vertical cross-sectional view of the second exemplary structure after formation of an interconnect-level dielectric layer and capacitor via trenches according to the second embodiment of the present disclosure. FIG. 12B is a top-down view of the second exemplary structure of FIG. 12A. The vertical plane A-A′ is the cut plane of the vertical cross-sectional view of FIG. 12A.

FIG. 14A is a vertical cross-sectional view of the second exemplary structure after formation of a dielectric spacer layer and an outer electrode material layer according to the second embodiment of the present disclosure. FIG. 14B is a top-down view of the second exemplary structure of FIG. 14A. The vertical plane A-A′ is the cut plane of the vertical cross-sectional view of FIG. 14A.

FIG. 15A is a vertical cross-sectional view of the second exemplary structure after patterning the outer electrode material layer into an outer electrode according to the second embodiment of the present disclosure. FIG. 15B is a top-down view of the second exemplary structure of FIG. 15A. The vertical plane A-A′ is the cut plane of the vertical cross-sectional view of FIG. 15A.

FIG. 16A is a vertical cross-sectional view of the second exemplary structure after depositing a capacitor dielectric material layer according to the second embodiment of the present disclosure. FIG. 16B is a top-down view of the second exemplary structure of FIG. 16A. The vertical plane A-A′ is the cut plane of the vertical cross-sectional view of FIG. 16A.

FIG. 17A is a vertical cross-sectional view of the second exemplary structure after formation of via cavities according to the second embodiment of the present disclosure. FIG. 17B is a top-down view of the second exemplary structure of FIG. 17A. The vertical plane A-A′ is the cut plane of the vertical cross-sectional view of FIG. 17A.

FIG. 18A is a vertical cross-sectional view of the second exemplary structure after deposition of an inner electrode material layer according to the second embodiment of the present disclosure. FIG. 18B is a top-down view of the second exemplary structure of FIG. 18A. The vertical plane A-A′ is the cut plane of the vertical cross-sectional view of FIG. 18A.

FIG. 19A is a vertical cross-sectional view of the second exemplary structure after patterning the inner electrode material layer and the capacitor dielectric material layer according to the second embodiment of the present disclosure. FIG. 19B is a top-down view of the second exemplary structure of FIG. 19A. The vertical plane A-A′ is the cut plane of the vertical cross-sectional view of FIG. 19A.

FIG. 20A is a vertical cross-sectional view of the second exemplary structure after formation of an additional interconnect-level dielectric layer and additional metal interconnect structures according to the second embodiment of the present disclosure. FIG. 20B is a top-down view of the second exemplary structure of FIG. 20A. The vertical plane A-A′ is the cut plane of the vertical cross-sectional view of FIG. 20A.

FIG. 21 is a schematic circuit diagram of a driver circuit that can be derived from the first exemplary structure of FIGS. 11A and 11B or the second exemplary structure of FIGS. 20A and 20B according to an embodiment of the present disclosure.

FIG. 22 is a vertical cross-sectional view of the exemplary structure after formation of a three-dimensional memory device over the driver circuit including the first exemplary structure of FIGS. 11A and 11B or the second exemplary structure of FIGS. 20A and 20B according to an embodiment of the present disclosure.

### DETAILED DESCRIPTION

As discussed above, the present disclosure is directed to a semiconductor structure including via capacitors and methods for forming the same, the various aspects of which are discussed herein in detail.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

Generally, a semiconductor package (or a “package”) refers to a unit semiconductor device that can be attached to a circuit board through a set of pins or solder balls. A semiconductor package may include a semiconductor chip (or a “chip”) or a plurality of semiconductor chips that are bonded thereamongst, for example, by flip-chip bonding or another chip-to-chip bonding. A package or a chip may include a single semiconductor die (or a “die”) or a plurality of semiconductor dies. A die is the smallest unit that can independently execute external commands or report status. Typically, a package or a chip with multiple dies is capable of simultaneously executing as many number of external commands as the total number of planes therein. Each die includes one or more planes. Identical concurrent operations can be executed in each plane within a same die, although there may be some restrictions. In case a die is a memory die, i.e., a die including memory elements, concurrent read operations, concurrent write operations, or concurrent erase operations can be performed in each plane within a same memory die. In a memory die, each plane contains a number of memory blocks (or “blocks”), which are the smallest unit that can be erased by in a single erase operation. Each memory block contains a number of pages, which are the smallest units that can be selected for programming. A page is also the smallest unit that can be selected to a read operation.

A memory array includes a peripheral (i.e., driver) circuit, which includes sense amplifier circuits that are electrically connected to bit lines to determine the state of each memory cell, i.e., to determine whether a specific memory cell encodes “0” or “1.” The sense amplifiers may function differently in different circuit components, and generally include a field effect transistor and a set of metal lines providing electrical connection to each electrical node (e.g., gate, source or drain) of the field effect transistor. Portions of the metal lines extending in the same direction (e.g., in the source to drain direction of the transistors) in regions overlying the field effect transistors of the sense amplifiers are referred to herein as metal tracks.

Capacitors are often integrated into the peripheral circuits to reduce signal instability or noise. However, incorporating capacitors into compact circuits is challenging because device space is limited. For example, in peripheral circuits of a memory device, capacitors are located in specific locations to ensure that signals remain stable, noise is minimized, and voltage levels are maintained. The capacitor location becomes difficult as devices become smaller and space for capacitors is reduced.

According to an aspect of the present disclosure, via capacitors are formed within via cavities located in or above vacant spaces between bit line switching transistors of a sense amplifier circuit. Thus, the via capacitors are positioned in unused spaces between circuit components, which reduces overall size of the peripheral circuit. The embodiment via capacitors can be integrated directly into the spaces between circuit components, such as bit line switching transistors by using vertical connections. The embodiment via capacitors can be manufactured with the addition of only few additional processing steps to a standard sequence of processing steps without necessarily using any extra material layers. Various embodiments of the present disclosure are now described with reference to accompanying figures.

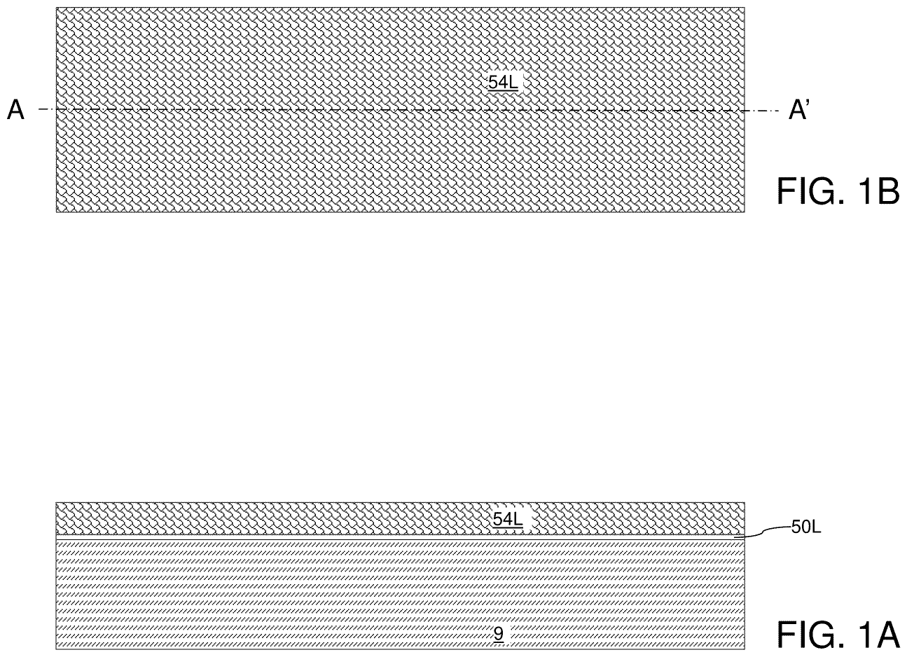

Referring to FIGS. 1A and 1B, a first exemplary structure according to a first embodiment of the present disclosure is illustrated, which comprises a semiconductor substrate 9. The semiconductor substrate 9 may be a bulk semiconductor substrate or a semiconductor-on-insulator substrate. For example, the semiconductor substrate 9 may comprise a commercially available silicon wafer or a silicon-on-insulator substrate.

A gate dielectric material layer 50L can be formed on a top surface of the semiconductor substrate 9. A lower gate electrode material layer 54L may be formed over the gate dielectric material layer 50L. For example, the lower gate electrode material layer 54L may comprise doped polysilicon having a thickness in a range from 60 nm to 200 nm, although lesser or greater thicknesses may also be employed.

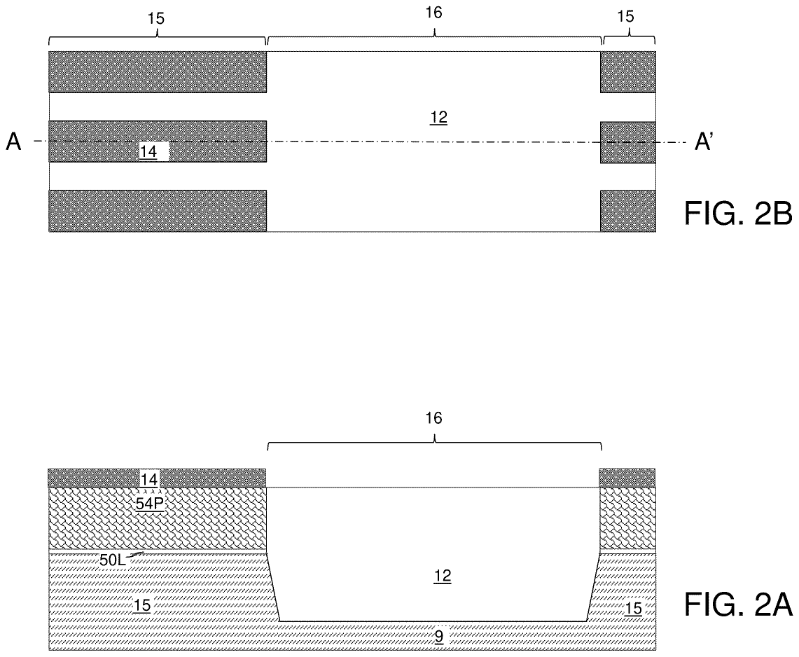

Referring to FIGS. 2A and 2B, a hard mask layer 14 can be formed over the lower gate electrode material layer 54L by depositing a blanket (i.e., unpatterned) hard mask material layer (such as a silicon nitride layer or another suitable hard mask layer), by applying and patterning a photoresist layer (not shown) over the blanket hard mask material layer, and by transferring the pattern in the patterned photoresist layer through the blanket hard mask material layer, for example, by performing an anisotropic etch process. The photoresist layer can be subsequently removed, for example, by ashing. Remaining patterned portions of the blanket hard mask material layer constitute the hard mask layer 14. The hard mask layer 14 may have the pattern of active regions 15 to be subsequently employed to form semiconductor devices. As used herein, active regions 15 refer to regions in which top surface segments of the semiconductor material of the semiconductor substrate 9 are physically exposed to allow subsequent construction of semiconductor devices thereupon. For example, the active regions 15 include all regions in which source, drain regions and channel regions of field effect transistors or other passive electrical components (such as resistors, etc.) employing surface portions of the semiconductor substrate 9 are to be subsequently formed.

An anisotropic etch process can be performed to etch unmasked portions of the lower gate electrode material layer 54L and the gate dielectric material layer 50L and unmasked regions of an upper portion of the semiconductor substrate 9. Shallow trenches are formed through the lower gate electrode material layer 54L and the gate dielectric material layer 50L and in an upper portion of the semiconductor substrate 9. The depth of the bottom surface of the shallow trench from the horizontal plane including the top surface of the semiconductor substrate 9 may be in a range from 100 nm to 400 nm, although lesser or greater depths may also be employed. Each patterned portion of the lower gate electrode material layer 54L is herein referred to as a lower gate electrode material portion 54P. Each lower gate electrode material portion 54P may have the same horizontal cross-sectional shape as the shape of the top surface of a respective underlying active region 15 within the semiconductor substrate 9. The gate dielectric material layer 50L as formed at the processing steps of FIGS. 1A and 1B is divided into a plurality of gate dielectric material layers 50L. Each vertical stack of an active region 15, a gate dielectric material layer 50L, a lower gate electrode material portion 54P, and a discrete patterned portion of the hard mask layer 14 may be laterally surrounded by the shallow trench.

A dielectric fill material, such as silicon oxide, can be deposited in the shallow trench by a conformal deposition process. A planarization process, such as a chemical mechanical polishing process, can be performed to remove portions of the dielectric fill material that overlie the horizontal plane including the top surface of the hard mask layer 14. A selective isotropic etch process can be performed to vertically recess the dielectric fill material selectively to the material of the hard mask layer 14. The duration of the selective isotropic etch process can be selected such that the recessed top surface of the remaining portion of the dielectric fill material is formed at or about the horizontal plane including the top surfaces of the lower gate electrode material portions 54P. The remaining portion of the dielectric fill material constitutes a shallow trench isolation structure 12. The hard mask layer 14 can be subsequently removed, for example, by performing a selective etch process that etches the material of the hard mask layer 14 selectively to the materials of the shallow trench isolation structure 12 and the lower gate electrode material portions 54P. The shallow trench isolation structure 12 comprises a lower portion embedded in an upper portion of the semiconductor substrate 9 and further comprises an upper portion protruding above the horizontal plane including the top surface of the semiconductor substrate 9.

According to an aspect of the present disclosure, a gap region 16 is provided between neighboring pairs or neighboring arrays of active regions 15 (e.g., regions where field effect transistors will be formed) of the semiconductor substrate 9 such that a region of the shallow trench isolation structure 12 continuously extends between the neighboring pairs or neighboring arrays of active regions 15. The lateral dimensions of the gap regions 16 may be greater than 100 nm, and preferably greater than 300 nm. The gap region 16 is subsequently employed to form via capacitors of embodiments of the present disclosure.

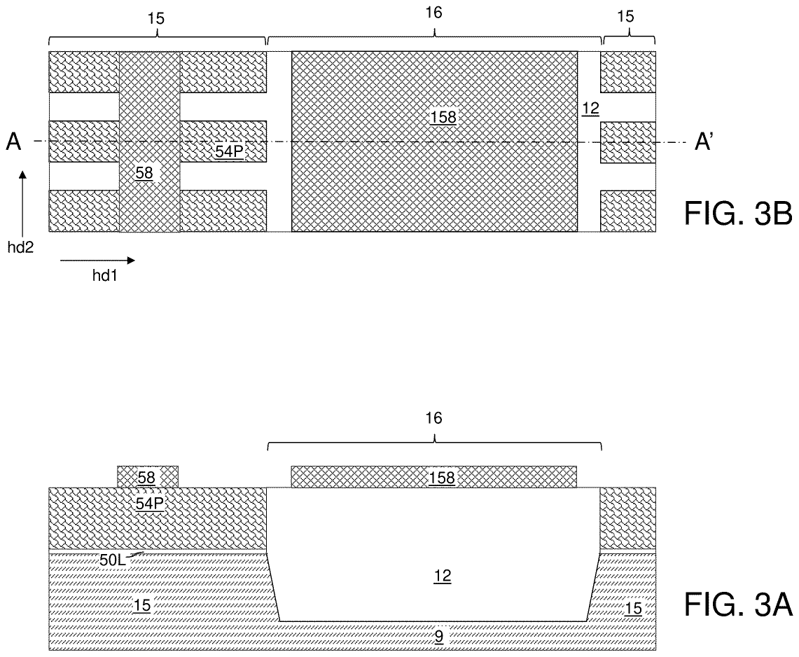

Referring to FIGS. 3A and 3B, an upper gate electrode material layer can be deposited over the lower gate electrode material portions 54P and the shallow trench isolation structure 12, and can be patterned into upper gate electrodes 58 and a conductive plate 158. The upper gate electrode material layer may comprise any electrically conductive material that is suitable for a gate electrode of a transistor. For example, the upper gate electrode material layer may comprise a metal, such as tungsten (W), molybdenum (Mo), platinum (Pt), or ruthenium (Ru), a conductive metal nitride, such as titanium nitride (TiN), tantalum nitride (TaN), or tungsten nitride (WN), and/or a metal silicide, such as cobalt silicide, nickel silicide, titanium silicide, and/or another suitable conductive gate material.

The thickness of the upper gate electrode material layer may be in a range from 20 nm to 100 nm, although lesser or greater thicknesses may also be employed. The upper gate electrodes 58 have the pattern of gate electrodes of field effect transistors to be subsequently formed. The conductive plate 158 is formed within the gap region 16 over the shallow trench isolation structure 12. In the illustrated example, the conductive plate 158 is formed within a rectangular gap area 16 that is filled entirely within the shallow trench isolation structure 12, and is free of the active regions 15 of the semiconductor substrate 9. In an illustrative example, two parallel edges of the conductive plate 158 may be laterally spaced apart from each other along a first horizontal direction hd1 by a width in a range from 100 nm to 2,000 nm, such as from 150 nm 1,000 nm, and may laterally extend along a second horizontal direction.

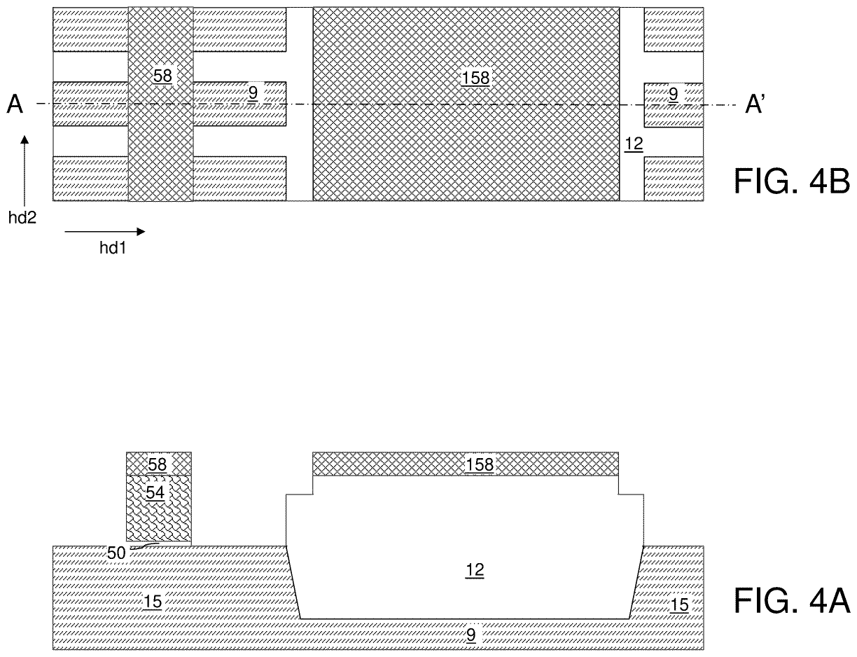

Referring to FIGS. 4A and 4B, selective anisotropic etch processes can be performed to transfer the pattern of the upper gate electrodes 58 through the lower gate electrode material portions 54P and the gate dielectric material layer 50L. For example, a first selective anisotropic etch process can be performed to etch unmasked portions of the lower gate electrode material portions 54P selectively to the materials of the upper gate electrodes 58, the shallow trench isolation structure 12, and the gate dielectric material layers 50L. The lower gate electrode material portions 54P are patterned into lower gate electrodes 54. Each contiguous combination of an upper gate electrode 58 and at least one lower gate electrode 54 constitutes a gate electrode (54, 58) located in a respective active region 15. Portions of the shallow trench isolation structure 12 that are not masked by the conductive plate 158 or the upper gate electrodes 58 may be recessed to provide stepped surfaces around the edges of the conductive plate 158 and the upper gate electrodes 58. Subsequently, a second elective anisotropic etch process can be performed to etch unmasked portions of the gate dielectric material layers 50L. Each patterned portion of the gate dielectric material layers 50L comprises a gate dielectric 50.

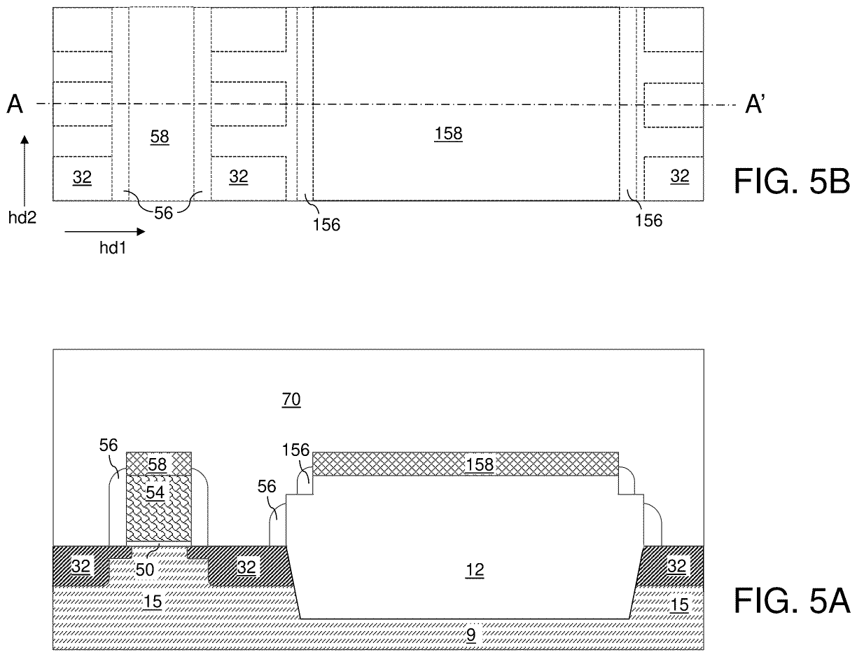

Referring to FIGS. 5A and 5B, various semiconductor devices can be formed on and/or in the active regions 15 of the semiconductor substrate 9. For example, doped source and drain regions 32 for field effect transistors may be formed on and/or in the active regions 15 of the semiconductor substrate 9 by ion implantation and/or by selective growth. The portion of the active region located between source and drain regions of the same transistor comprises a channel region of the transistor. Dielectric gate spacers 56 are formed on sidewalls of the gate electrodes (54, 58) and additional dielectric spacers 156 may be formed on vertical surfaces of the shallow trench isolation structure 12 by deposition of one or more dielectric layers (e.g., silicon oxide and/or silicon nitride) and an anisotropic sidewall spacer etch.

A contact-level dielectric layer 70 can be formed over the semiconductor devices and the shallow trench isolation structure 12. The top surface of the contact-level dielectric layer 70 may be planarized, for example, by performing a chemical mechanical polishing process. The vertical distance between the top surface of the contact-level dielectric layer 70 and the top surface of the conductive plate 158 may be in a range from 100 nm to 300 nm, although lesser or greater vertical distances may also be employed.

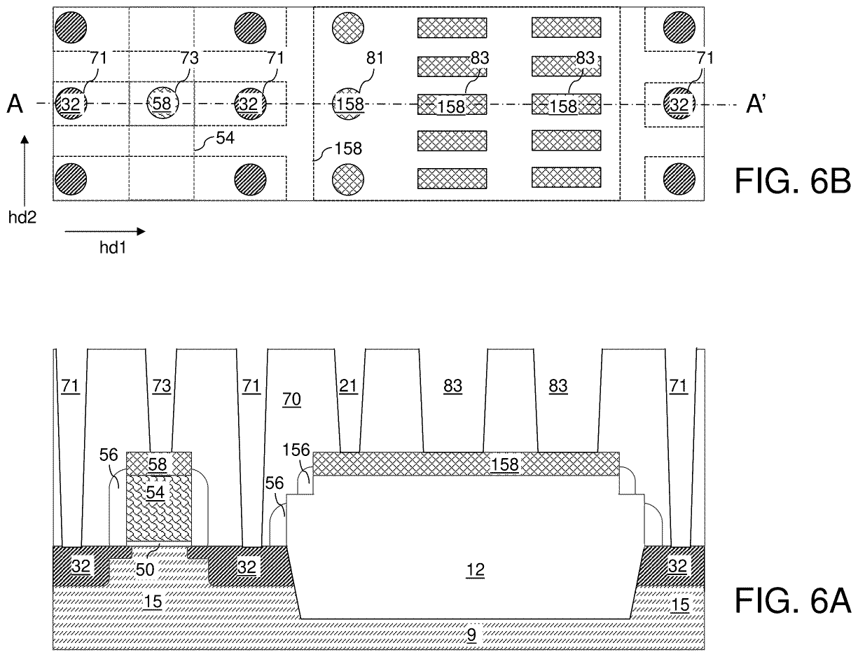

Referring to FIGS. 6A and 6B, a photoresist layer (not shown) can be applied over the contact-level dielectric layer 70, and can be lithographically patterned to form discrete openings. An anisotropic etch process can be performed to transfer the pattern of the openings in the photoresist layer through the contact-level dielectric layer 70. The anisotropic etch process can have an etch chemistry that etches the material of the contact-level dielectric layer 70 selectively to the materials of the upper gate electrodes 58, the conductive plate 158, and the semiconductor material of the source and drain regions 32. Various cavities (71, 73, 21, 83) are formed through the contact-level dielectric layer 70 underneath the openings in the photoresist layer. The photoresist layer can be subsequently removed, for example, by ashing.

The various cavities (71, 73, 21, 83) comprise device contact via cavities (71, 73) formed over various electrical nodes of the semiconductor devices (e.g., source, drain and gate electrodes of transistors), capacitor via trenches 83 that are formed over first top surface segments of the conductive plate 158, and electrode connection via cavities 21 that are formed over second top surface segments of the conductive plate 158. Electrical nodes of the various semiconductor devices can be physically exposed under the device contact via cavities (71, 73). For example, the device contact via cavities (71, 73) may comprise source and drain contact via cavities 71 that are formed over the source and drain regions 32, and gate contact via cavities 73 that are formed over the gate electrodes (54, 58). Additional device contact via cavities may be formed over electrical nodes of additional semiconductor devices (not shown). The lateral dimensions of the device contact via cavities (71, 73) may be in a range from 25 nm to 200 nm, although lesser or greater lateral dimensions may also be employed.

The capacitor via trenches 83 may be formed in an array configuration, which may be, for example, a one-dimensional array configuration or a two-dimensional array configuration. In the illustrated example, the capacitor via trenches 83 are formed in a two-dimensional rectangular array configuration. Generally, each capacitor via trench 83 has a width that is greater than twice the sum of a thickness of an outer electrode material layer and the thickness of the capacitor dielectric material layer to be subsequently deposited. For example, each capacitor via trench 83 may have a width that is greater than 25 nm, and/or greater than 50 nm. Length of each capacitor via trench 83 may be in a range from 100 nm to 10 microns, although lesser or greater lengths may also be employed.

The electrode connection via cavities 21 via cavities may be formed as discrete via cavities or as a one-dimensional array of via cavities. The lateral dimensions of the electrode connection via cavities 21 may be about the same as the lateral dimensions of the device contact via cavities (71, 73).

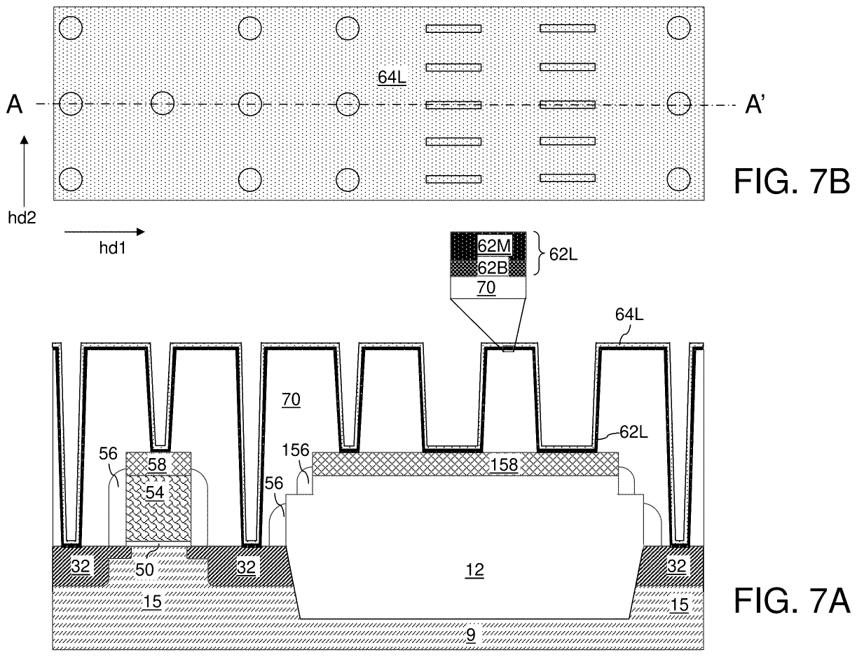

Referring to FIGS. 7A and 7B, an outer electrode material layer 62L can be conformally deposited in peripheral regions of the various cavities (71, 73, 21, 83) and over the top surface of the contact-level dielectric layer 70. The outer electrode material layer 62L may comprise at least one electrically conductive material layer (62B, 62M). For example, the outer electrode material layer 62L may comprise a metallic nitride barrier material layer 62B and a high-conductivity metal layer 62M. The metallic nitride barrier material layer 62B may comprise TiN, TaN, WN, and/or MoN, and may have a thickness in a range from 2 nm to 10 nm. The high-conductivity metal layer 62M may comprise a metal such as Ta, Ti, W, Mo, Ru, Co, etc., and may have a thickness in a range from 5 nm to 50 nm, although lesser or greater thicknesses may also be employed.

A capacitor dielectric material layer 64L can be conformally deposited over the outer electrode material layer 62L by a conformal deposition process. The capacitor dielectric material layer 64L comprises a capacitor dielectric material such as silicon oxide, aluminum oxide, a transition metal oxide (e.g., tantalum oxide, niobium oxide, barium strontium titanate, etc.), or a combination thereof. The thickness of the capacitor dielectric material layer 64L may be in a range from 5 nm to 20 nm, although lesser or greater thicknesses may also be employed.

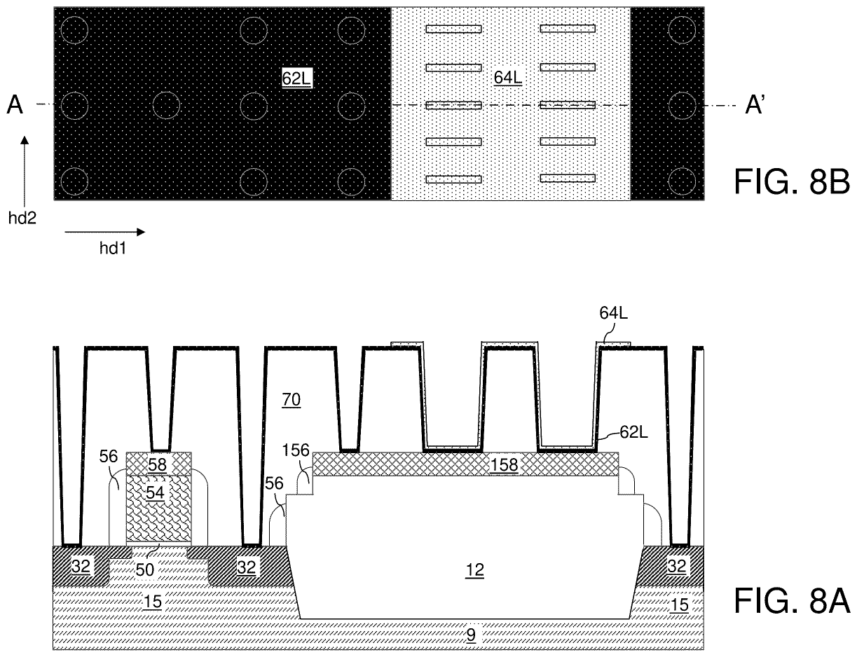

Referring to FIGS. 8A and 8B, a photoresist layer (not shown) is applied over the capacitor dielectric material layer 64L, and is lithographically patterned to cover the areas of the capacitor via trenches 83 without covering the areas of the device contact via cavities (71, 73) and in the electrode connection via cavities 21. A selective etch process can be performed to etch physically exposed portions of the capacitor dielectric material layer 64L. All remaining portion of the capacitor dielectric material layer 64L may continuously extend over the areas of the capacitor via trenches 83. The outer electrode material layer 62L may be physically exposed in the areas that are not covered by the photoresist layer. The photoresist layer may be subsequently removed, for example, by ashing.

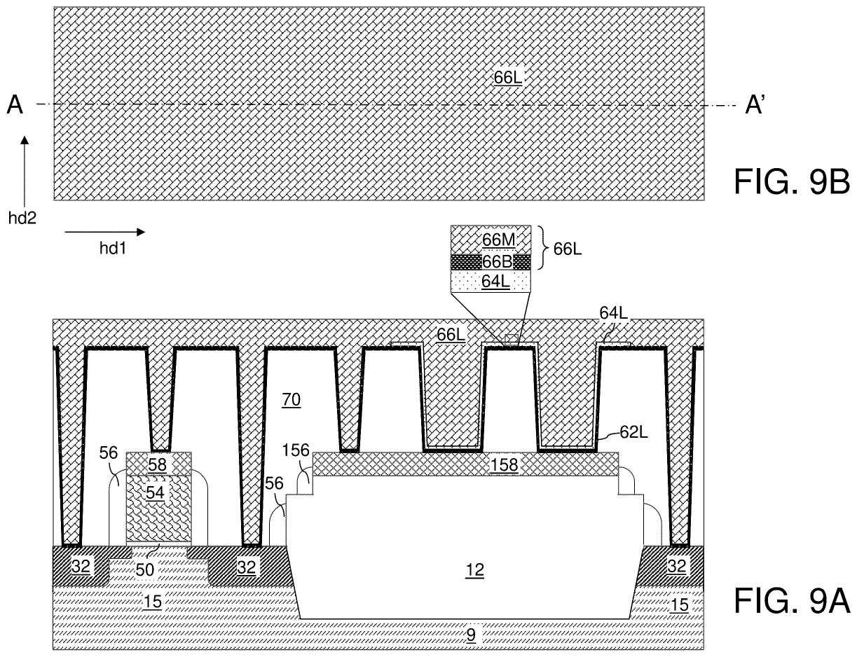

Referring to FIGS. 9A and 9B, at least one electrically conductive material can be deposited within the unfilled volumes of the various cavities (71, 73, 21, 83) and over the contact-level dielectric layer 70 to form an inner electrode material layer 66L. In one embodiment, the inner electrode material layer 66L may comprise at least one electrically conductive material layer (66B, 66M). For example, the inner electrode material layer 66L may comprise a metallic nitride barrier material layer 66B and a high-conductivity metal layer 66M. The metallic nitride barrier material layer 66B may comprise TiN, TaN, WN, and/or MoN, and may have a thickness in a range from 6 nm to 10 nm. The high-conductivity metal layer 66M may comprise a metal such as Ta, Ti, W, Mo, Ru, Co, Nb, etc. The thickness of the high-conductivity metal layer 66M is selected to fill the entirety of the unfilled volumes of the various cavities (71, 73, 21, 83). In one embodiment, the thickness of the inner electrode material layer 66L can be selected to enable patterning of metal lines and metal pads from horizontally-extending portions of the inner electrode material layer 66L that overlie the contact-level dielectric layer 70. For example, the thickness of the inner electrode material layer 66L may be in a range from 50 nm to 200 nm, although lesser or greater thicknesses may also be employed.

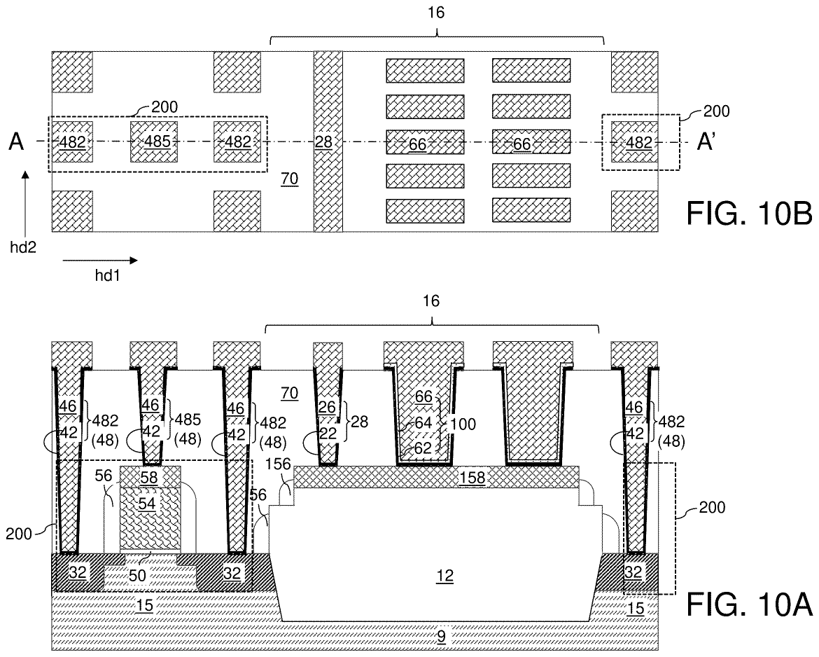

Referring to FIGS. 10A and 10B, a photoresist layer (not shown) can be applied over the inner electrode material layer 66L, and can be lithographically patterned into discrete photoresist material portions that overlie a respective one of the various cavities (71, 73, 21, 83). At least one anisotropic etch process can be performed to etch unmasked portions of the inner electrode material layer 66L, the capacitor dielectric material layer 64L, and the outer electrode material layer 62L.

Patterned portions of the outer electrode material layer 62L located in or above the capacitor via trenches 83 comprise outer electrodes 62 of capacitors. Patterned portions of the outer electrode material layer 62L located in or above the device contact via cavities (71, 73) comprise outer conductive layers 42 having a same material composition and a same thickness as the outer electrodes 62. Patterned portions of the outer electrode material layer 62L located in or above the electrode connection via cavities 21 comprise outer conductive layers 22 having a same material composition and a same thickness as the outer electrodes 62.

Patterned portions of the capacitor dielectric material layer 64L comprise capacitor dielectrics 64. Patterned portions of the inner electrode material layer 66L located in or above the capacitor via trenches 83 comprise inner electrodes 66 of capacitors. Patterned portions of the inner electrode material layer 66L located in or above the device contact via cavities (71, 73) comprise inner conductive fill material portions 46 having a same set of at least one conductive material as the inner electrodes 66 and in direct contact with a respective outer conductive layer 42. Patterned portions of the inner electrode material layer 66L located in or above the electrode connection via cavities 21 comprise inner conductive fill material portions 26 having a same set of at least one conductive material as the inner electrodes 66 and in direct contact with a respective outer conductive layer 22.

Each contiguous combination of an outer electrode 62, a capacitor dielectric 64, and an inner electrode 66 constitutes a via capacitor 100, i.e., a capacitor having a via configuration (e.g., a trench capacitor having a relatively small length relative to its width in a horizontal plate). Each contiguous combination of an outer conductive layer 42 and an inner conductive fill material portion 46 that fills a respective device contact via cavity (71, 73) constitutes a contact-level metal interconnect structure 48. The contact-level metal interconnect structures 48 may comprise source and drain contact via structures (i.e., source and drain electrodes) 482 contacting a respective source and drain region 32, and gate contact via structures 485 contacting a respective gate electrode (54, 58). Each contiguous combination of an outer conductive layer 22 and an inner conductive fill material portion 26 that fills a respective electrode connection via cavity 21 constitutes an electrode connection via structure 28 that contacts the conductive plate 158. In one embodiment, a plurality of electrode connection via structures 28 may be interconnected among one another above the horizontal plane including the top surface of the contact-level dielectric layer 70.

According to an embodiment of the present disclosure, the via capacitor (62, 64, 66) can be formed in each capacitor via trench 83. The via capacitor (62, 64, 66) comprises an outer electrode 62, a capacitor dielectric 64, and an inner electrode 66. The outer electrode 62 comprises a horizontally-extending bottom conductive plate portion contacting the conductive plate 158, and a tubular vertically-extending conductive portion having outer sidewall segments that contact the contact-level dielectric layer 70. In one embodiment, the outer electrode 62 comprises a horizontally-extending upper conductive plate portion adjoined to a top end of the tubular vertically-extending conductive portion and having a bottom surface that contacts a segment of a top surface of the contact-level dielectric layer 70.

In one embodiment, the capacitor dielectric 64 comprises a horizontally-extending bottom dielectric plate portion; a tubular vertically-extending dielectric portion having outer sidewall segments that contact the tubular vertically-extending conductive portion; and a horizontally-extending upper dielectric plate portion adjoined to the tubular vertically-extending dielectric portion and overlying the horizontally-extending upper conductive plate portion. In one embodiment, the horizontally-extending upper dielectric plate portion may have a frame shape. In one embodiment, sidewalls of the horizontally-extending upper dielectric plate portion are vertically coincident with sidewalls of the horizontally-extending upper conductive plate portion of the outer electrode 62.

In one embodiment, the inner electrode 66 comprises: a via electrode portion laterally surrounded by a tubular vertically-extending dielectric portion of the capacitor dielectric 64; and a top plug electrode portion overlying the via electrode portion and having a greater lateral extent than a maximum lateral extent of the via electrode portion. In one embodiment, the capacitor dielectric 64 comprises a horizontally-extending upper dielectric plate portion overlying a horizontal plane including the top surface of the contact-level dielectric layer 70; and sidewalls of the top plug electrode portion are vertically coincident with sidewalls of the horizontally-extending upper dielectric plate portion of the capacitor dielectric 64.

An electrode connection via structure 28 vertically extends through the contact-level dielectric layer 70, and contacts the conductive plate 158. The electrode connection via structure 28 may have a top surface located above the horizontal plane including the top surface of the contact-level dielectric layer 70. In one embodiment, the electrode connection via structure 28 comprises: an outer conductive layer 22 having a same material composition and a same thickness as the outer electrode 62; and an inner conductive fill material portion 26 comprising a same set of at least one conductive material as the inner electrode 66 and in direct contact with the outer conductive layer 42.

A field effect transistor 200 include the source and drain regions 32 separated by a channel region (e.g., upper portion of the semiconductor active region 15), a gate electrode (54, 58), a gate dielectric 50 located between the channel region and the gate electrode, and the source and drain electrodes 482. The capacitors 100 are formed in the gap region 16 between the adjacent transistors 200. The conductive plate 158 which electrically connects the outer electrodes of the capacitors 100 is formed at the same time and from the same layer as at least a portion of the gate electrode (54, 58) of field effect transistors 200 of the peripheral circuit.

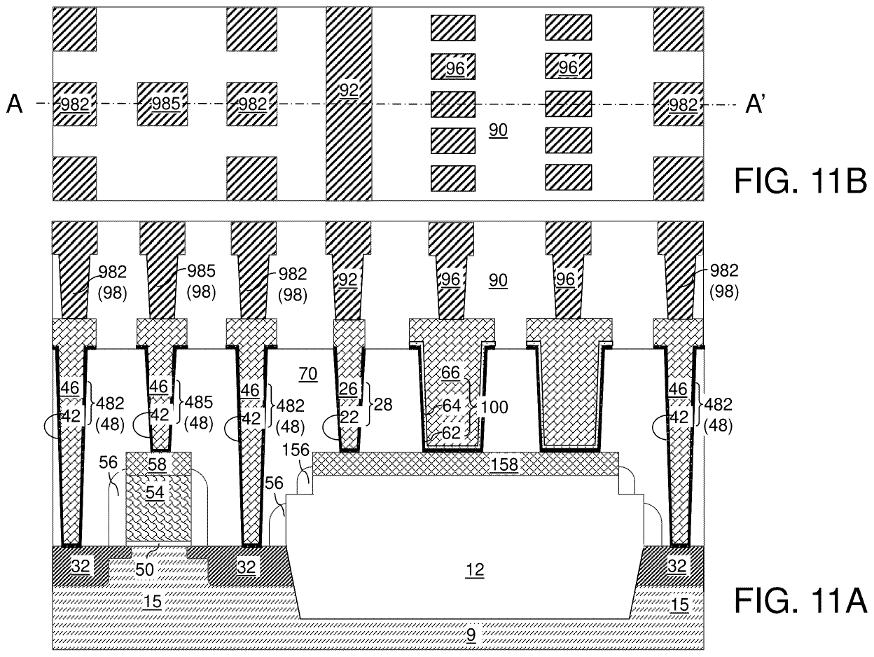

Referring to FIGS. 11A and 11B, an interconnect-level dielectric layer 90 can be formed over the contact-level dielectric layer 70, the via capacitors 100, the contact-level metal interconnect structures 48, and the electrode connection via structures 28. Interconnect-level metal interconnect structures (96, 92, 98) can be formed in the interconnect-level dielectric layer 90. The interconnect-level metal interconnect structures (96, 92, 98) may comprise inner electrode connection structures 96 that are electrically connected to the inner electrode 66 of a respective via capacitor 100, outer electrode connection structures 92 that are electrically connected to the conductive plate 158 and the outer electrodes 62 of the via capacitors 100, and device connection metal interconnect structures 98 that are electrically connected to a respective one of the contact-level metal interconnect structures 48. For example, the device connection metal interconnect structures 98 may comprise source and drain connection structures 982 and gate connection structures 985.

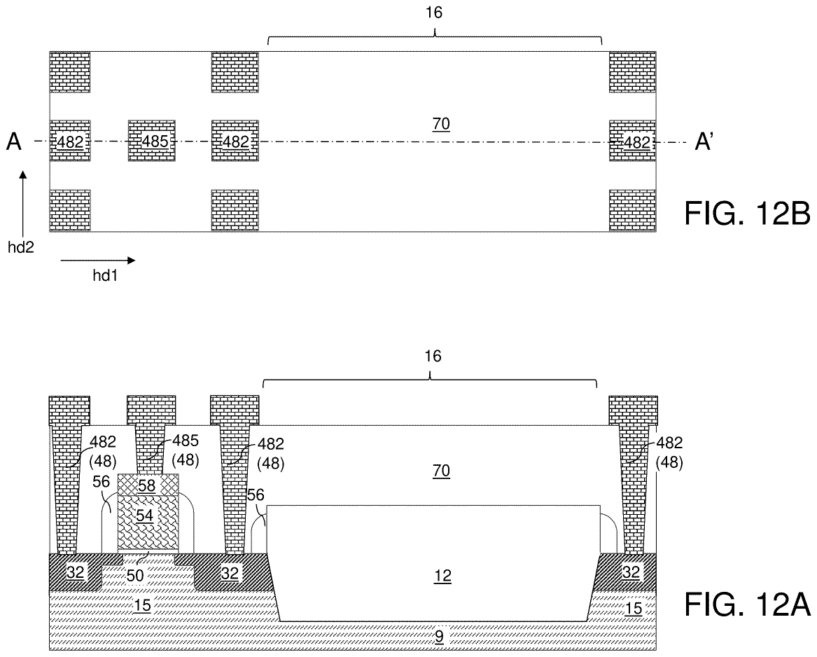

Referring to FIGS. 12A and 12B, a second exemplary structure according to a second embodiment of the present disclosure can be derived from the first exemplary structure illustrated in FIGS. 5A and 5B by omitting formation of the conductive plate 158, and by forming various contact-level metal interconnect structures 48. For example, the contact-level metal interconnect structures 48 may comprise source and drain contact via structures 482 contacting a respective source and drain region 32, and gate contact via structures 485 contacting a respective gate electrode (54, 58). The contact-level metal interconnect structures 48 may be formed, for example, by forming via cavities through the contact-level dielectric layer 70, by depositing at least one conductive material in the via cavities, and by patterning the at least one conductive material.

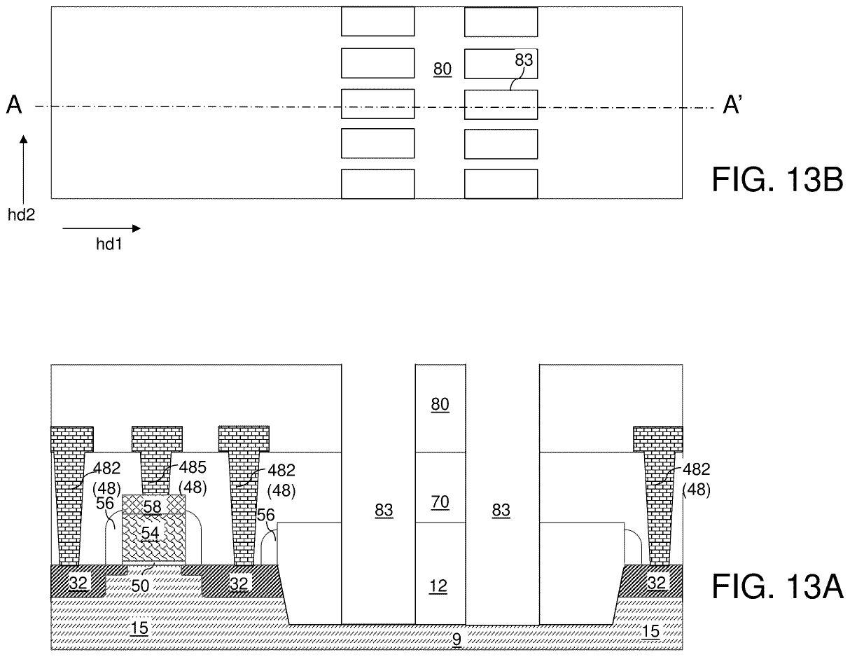

Referring to FIGS. 13A and 13B, a first interconnect-level dielectric layer 80 can be formed over the contact-level dielectric layer 70. The first interconnect-level dielectric layer 80 comprises a dielectric material such as silicon oxide. The thickness of the first interconnect-level dielectric layer 80 may be in a range from 200 nm to 600 nm, although lesser or greater thicknesses may also be employed.

A photoresist layer (not shown) can be applied over the first interconnect-level dielectric layer 80, and can be lithographically patterned to form discrete openings. The discrete openings are formed within the area of the shallow trench isolation structure 12. An anisotropic etch process can be performed to transfer the pattern of the openings in the photoresist layer through the first interconnect-level dielectric layer 80, the contact-level dielectric layer 70, and the shallow trench isolation structure 12. In one embodiment, the anisotropic etch process can have an etch chemistry that etches the materials of the first interconnect-level dielectric layer 80, the contact-level dielectric layer 70, and the shallow trench isolation structure 12 selectively to the material of the semiconductor substrate 9. Capacitor via trenches 83 are formed in the volumes from which the material portions of the first interconnect-level dielectric layer 80, the contact-level dielectric layer 70, and the shallow trench isolation structure 12 are removed. A surface segment of the semiconductor substrate 9 can be physically exposed underneath each capacitor via trench 83. Each capacitor via trench 83 may comprise a set of straight sidewalls that vertically extend from the horizontal plane including the top surface of the first interconnect-level dielectric layer 80 to a top surface segment of a portion of the semiconductor substrate 9 that underlies the shallow trench isolation structure 12.

The capacitor via trenches 83 may be formed in an array configuration, which may be, for example, a one-dimensional array configuration or a two-dimensional array configuration. In the illustrated example, the capacitor via trenches 83 are formed in a two-dimensional rectangular array configuration. Generally, each capacitor via trench 83 has a width that is greater than twice the sum of a thickness of an outer electrode material layer and the thickness of the capacitor dielectric material layer to be subsequently deposited. For example, each capacitor via trench 83 may have a width that is greater than 25 nm, and/or greater than 50 nm. Length of each capacitor via trench 83 may be in a range from 100 nm to 10 microns, although lesser or greater lengths may also be employed.

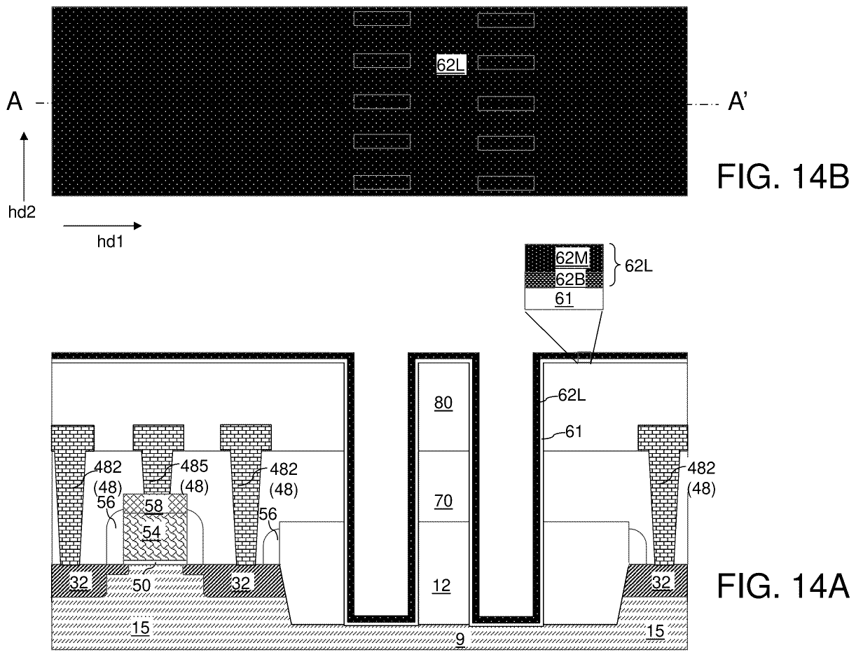

Referring to FIGS. 14A and 14B, a dielectric material such as silicon oxide or silicon nitride can be conformally deposited to form a dielectric spacer layer 61. The dielectric spacer layer 61 may be formed directly on the physically exposed top surface segments of the semiconductor substrate 9 and directly on sidewalls of the capacitor via trenches 83. The dielectric spacer layer 61 may comprise bottom dielectric spacer plate portions formed directly on bottom surfaces of the capacitor via trenches 83, and tubular dielectric spacer portions formed directly sidewalls of the capacitor via trenches 83. Each bottom spacer plate portion of the dielectric spacer layer 61 contacts a top surface segment of the portion of the semiconductor substrate 9 that underlies the shallow trench isolation structure 12.

An outer electrode material layer 62L can be conformally deposited on the dielectric spacer layer 61. The outer electrode material layer 62L may comprise at least one electrically conductive material layer (62B, 62M). For example, the outer electrode material layer 62L may comprise a metallic nitride barrier material layer 62B and a high-conductivity metal layer 62M. The metallic nitride barrier material layer 62B may comprise TiN, TaN, WN, and/or MoN, and may have a thickness in a range from 2 nm to 10 nm. The high-conductivity metal layer 62M may comprise a metal such as Ta, Ti, W, Mo, Ru, Co, Nb, etc., and may have a thickness in a range from 5 nm to 50 nm, although lesser or greater thicknesses may also be employed.

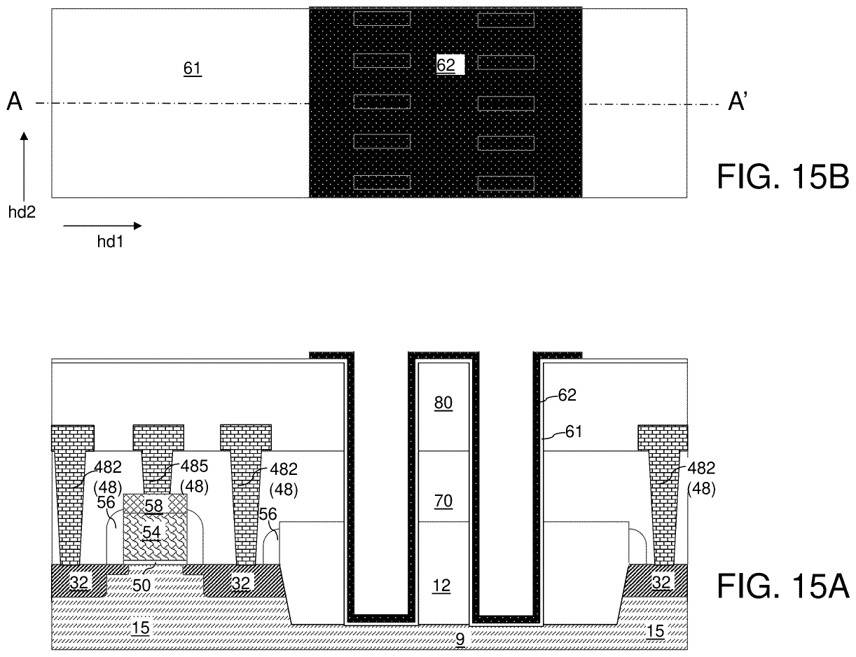

Referring to FIGS. 15A and 15B, a photoresist layer (not shown) can be applied over the outer electrode material layer 62L, and can be lithographically patterned to cover the areas of the capacitor via trenches 83. A selective etch process can be performed to remove unmasked portions of the outer electrode material layer 62L selectively to the material of the dielectric spacer layer 61 from outside the areas of the photoresist layer. A remaining portion of the outer electrode material layer 62L comprises an outer electrode 62. The outer electrode may continuously extend into a plurality of capacitor via trenches 83, and may comprise an upper horizontally-extending portion that overlies the first interconnect-level dielectric layer 80. The photoresist layer can be subsequently removed, for example, by ashing.

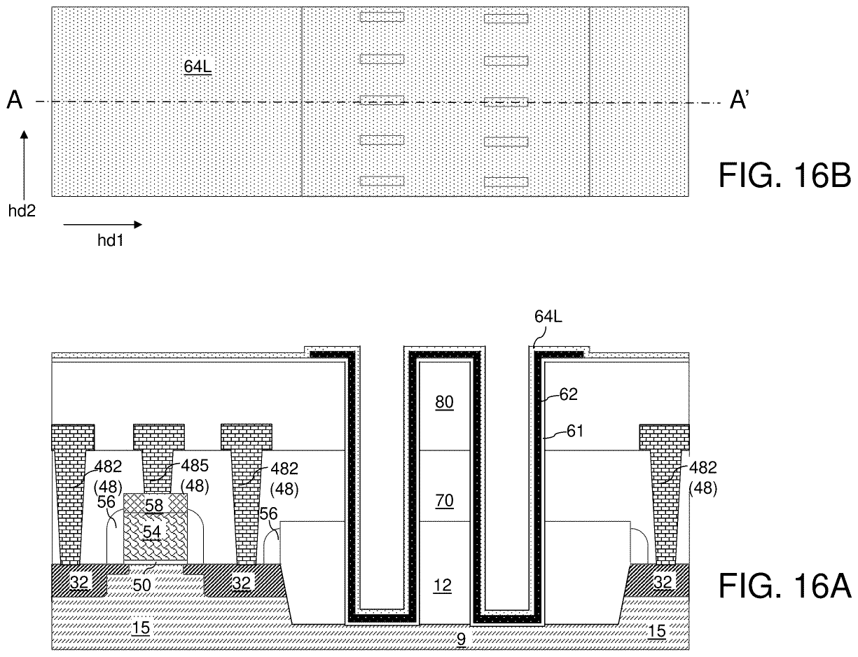

Referring to FIGS. 16A and 16B, a capacitor dielectric material layer 64L can be conformally deposited over the outer electrode 62 and the first interconnect-level dielectric layer 80 by a conformal deposition process. The capacitor dielectric material layer 64L comprises any suitable capacitor dielectric material as described above. The thickness of the capacitor dielectric material layer 64L may be in a range from 5 nm to 20 nm, although lesser or greater thicknesses may also be employed.

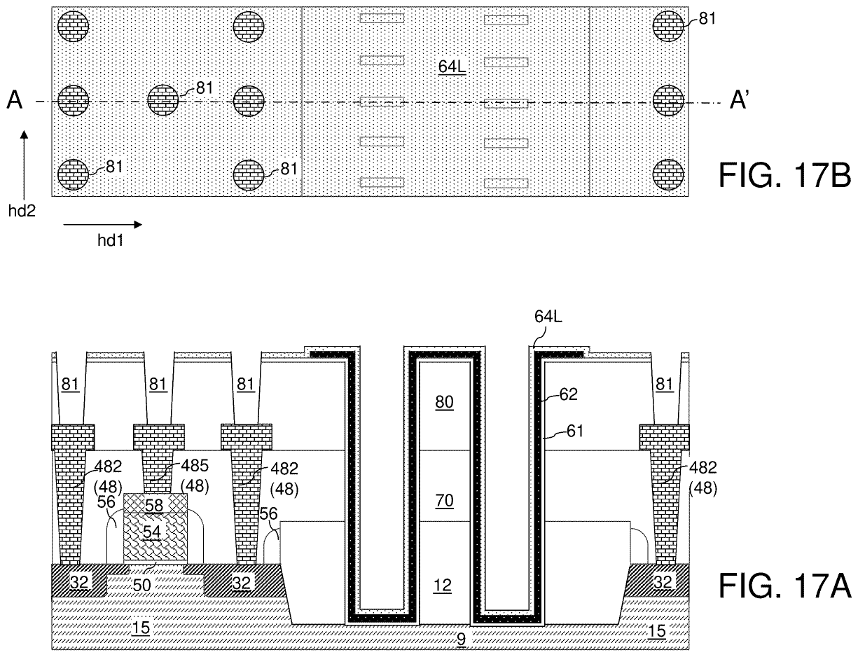

Referring to FIGS. 17A and 17B, a photoresist layer (not shown) can be applied over the contact-level dielectric layer 70, and can be lithographically patterned to form discrete openings over the contact-level metal interconnect structures 48. An anisotropic etch process can be performed to transfer the pattern of the openings in the photoresist layer through the capacitor dielectric material layer 64L, the dielectric spacer layer 61, and the first interconnect-level dielectric layer 80. The anisotropic etch process can have an etch chemistry that etches the materials of the capacitor dielectric material layer 64L, the dielectric spacer layer 61, and the first interconnect-level dielectric layer 80 selectively to the materials of the contact-level metal interconnect structures 48. Via cavities 81 are formed through the first interconnect-level dielectric layer 80 underneath the openings in the photoresist layer. The photoresist layer can be subsequently removed, for example, by ashing. A top surface of a contact-level metal interconnect structure 48 can be physically exposed underneath each via cavity 81 through the capacitor dielectric material layer 64L, the dielectric spacer layer 61, and the first interconnect-level dielectric layer 80.

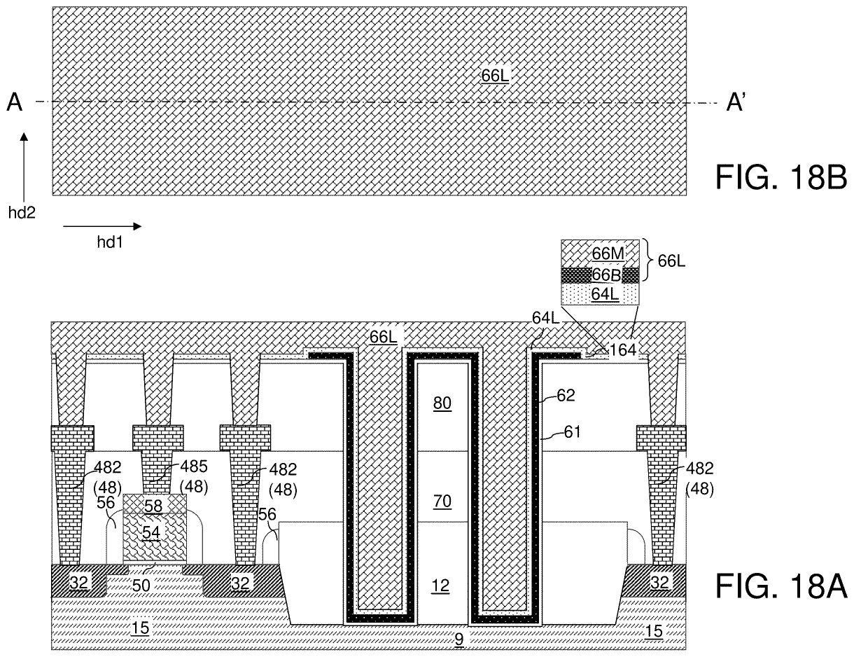

Referring to FIGS. 18A and 18B, at least one electrically conductive material can be deposited within the unfilled volumes of the capacitor via cavities 83 and the via cavities 81 to form an inner electrode material layer 66L. In one embodiment, the inner electrode material layer 66L may comprise at least one electrically conductive material layer (66B, 66M). For example, the inner electrode material layer 66L may comprise a metallic nitride barrier material layer 66B and a high-conductivity metal layer 66M. The metallic nitride barrier material layer 66B may comprise TiN, TaN, WN, and/or MoN, and may have a thickness in a range from 6 nm to 10 nm. The high-conductivity metal layer 66M may comprise a metal such as Ta, Ti, W, Mo, Ru, Co, Nb, etc. The thickness of the high-conductivity metal layer 66M is selected to fill the entirety of the unfilled volumes of the capacitor via cavities 83 and the via cavities 81. In one embodiment, the thickness of the inner electrode material layer 66L can be selected to enable patterning of metal lines and metal pads from horizontally-extending portions of the inner electrode material layer 66L that overlie the first interconnect-level dielectric layer 80. For example, the thickness of the inner electrode material layer 66L may be in a range from 50 nm to 200 nm, although lesser or greater thicknesses may also be employed.

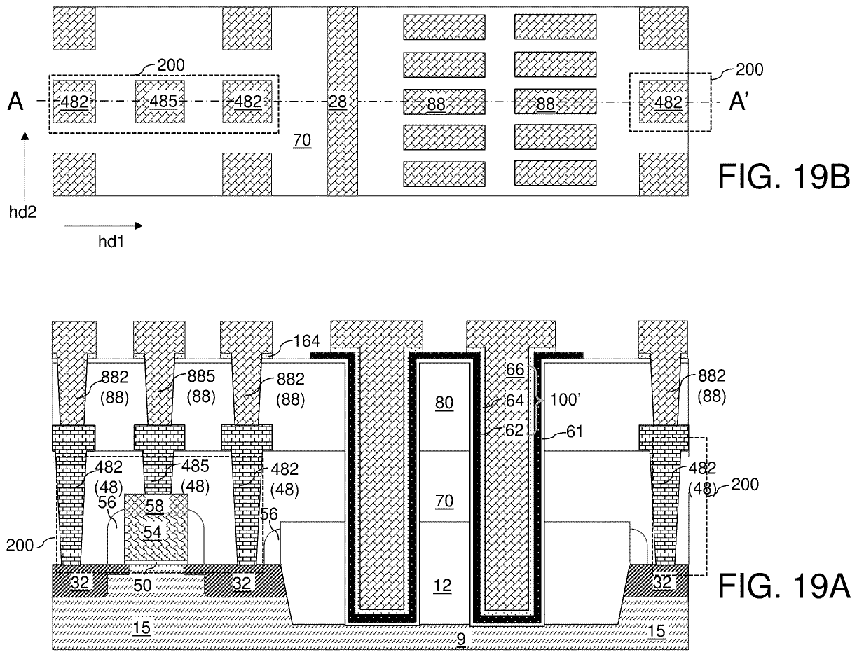

Referring to FIGS. 19A and 19B, a photoresist layer (not shown) can be applied over the inner electrode material layer 66L, and can be lithographically patterned into discrete photoresist material portions that overlie a respective one of the capacitor via cavities 83 and the via cavities 81. At least one anisotropic etch process can be performed to etch unmasked portions of the inner electrode material layer 66L and the capacitor dielectric material layer 64L. The at least one anisotropic etch process may comprise a first anisotropic etch process that patterns the inner electrode material layer 66L selectively to the material of the capacitor dielectric material layer 64L, and a second anisotropic etch process that patterns the capacitor dielectric material layer 64L selectively to the material of the outer electrode 62.

Patterned portions of the capacitor dielectric material layer 64L comprise capacitor dielectrics 64. Patterned portions of the inner electrode material layer 66L located in or above the capacitor via trenches 83 comprise inner electrodes 66 of capacitors. Patterned portions of the inner electrode material layer 66L located in or above the via cavities 81 comprise first interconnect-level metal interconnect structures 88 having a same set of at least one conductive material as the inner electrodes 66. The first interconnect-level metal interconnect structures 88 may comprise first source and drain connection metal interconnect structures 882 and first gate connection metal interconnect structures 885.

In summary, at least one electrically conductive material can be deposited to form the inner electrode material layer 66L. Patterned portions of the at least one electrically conductive material of the inner electrode material layer 66L comprise the inner electrodes 66, and additional patterned portions of the at least one electrically conductive material of the inner electrode material layer 66L comprise portions of metal interconnect structures, i.e., the first interconnect-level metal interconnect structures 88, that are electrically connected to the semiconductor devices, such as the transistors 200.

Via capacitors 100′ are formed in the capacitor via trenches 83. Each of the via capacitors 100′ comprises an outer electrode 62, a capacitor dielectric 64, and an inner electrode 66. The outer electrode 62 comprises a horizontally-extending bottom conductive plate portion contacting the conductive plate, and a tubular vertically-extending conductive portion having outer sidewall segments that contact the contact-level dielectric layer 70. An optional dielectric spacer layer 61 comprises bottom dielectric spacer plate portions located within the capacitor via trenches 83 and underlying a bottommost surface of a respective outer electrode 62. The dielectric spacer layer 61 also comprises tubular dielectric spacer portions located in the capacitor via trenches 83 and laterally surrounding a respective tubular vertically-extending conductive portion of the outer electrode 62. Further, the dielectric spacer layer 61 may also comprise a horizontally-extending spacer layer portion overlying the first interconnect-level dielectric layer 80.

In one embodiment, each capacitor via trench 83 vertically extends to a portion of the semiconductor substrate 9 that underlies the shallow trench isolation structure 12, and each bottom spacer plate portion of the dielectric spacer layer 61 contacts a top surface segment of the portion of the semiconductor substrate 9 that underlies the shallow trench isolation structure 12, to isolate the capacitor 100′ from the semiconductor substrate 9 In one embodiment, the outer electrode 62 comprises a horizontally-extending upper conductive plate portion adjoined to a top end of each tubular vertically-extending conductive portion and having a bottom surface that contacts a segment of a top surface of the horizontally-extending spacer layer portion of the dielectric spacer layer 61.

In one embodiment, the capacitor dielectric 64 comprises a horizontally-extending bottom dielectric plate portion, a tubular vertically-extending dielectric portion having outer sidewall segments that contact the tubular vertically-extending conductive portion, and a horizontally-extending upper dielectric plate portion adjoined to the tubular vertically-extending dielectric portion and overlying the horizontally-extending upper conductive plate portion; and sidewalls of the horizontally-extending upper dielectric plate portion are laterally offset inward relative to sidewalls of the horizontally-extending upper conductive plate portion of the outer electrode 62.

In one embodiment, each inner electrode 66 comprises a via electrode portion laterally surrounded by a tubular vertically-extending dielectric portion of the capacitor dielectric 64, and a top plug electrode portion overlying the via electrode portion and having a greater lateral extent than a maximum lateral extent of the via electrode portion; and the capacitor dielectric 64 comprises a horizontally-extending upper dielectric plate portion overlying a horizontal plane including a top surface of the interconnect-level dielectric layer 80; and sidewalls of the top plug electrode portion are vertically coincident with sidewalls of the horizontally-extending upper dielectric plate portion of the capacitor dielectric 64.

In one embodiment, contact-level metal interconnect structures 48 may be provided, each of which comprises a respective contact-level via portion that vertically extends through the contact-level dielectric layer 70 and contacts a respective electrical node of the semiconductor devices. In one embodiment, first interconnect-level metal interconnect structures 88 may be provided, each of which comprises a respective connection-level via portion that vertically extends through the first interconnect-level dielectric layer 80 and contacts a respective one of the contact-level metal interconnect structures 48. In one embodiment, the first interconnect-level metal interconnect structures 88 comprise a same set of at least one conductive material as the inner electrode 66, and are in direct contact with the first interconnect-level dielectric layer 80.

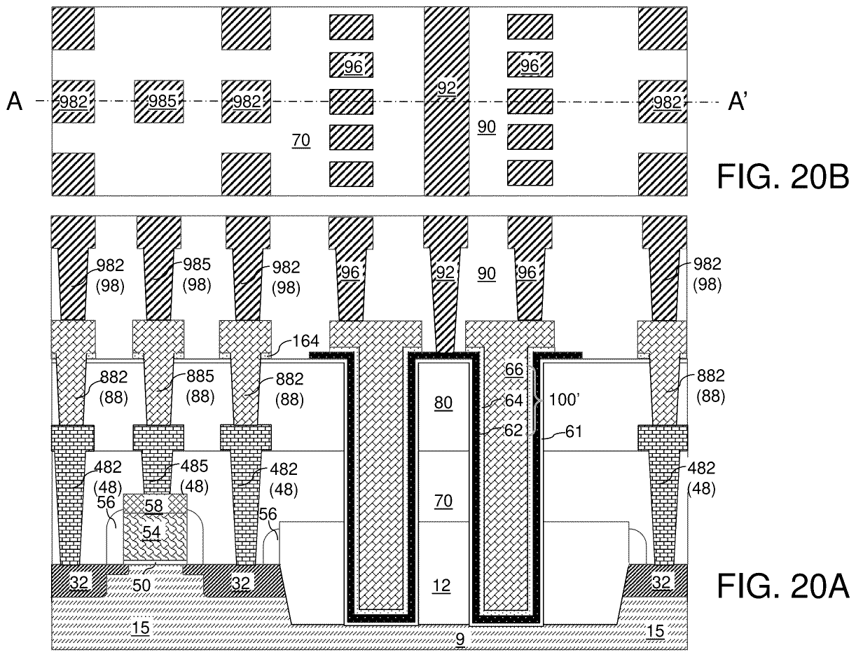

Referring to FIGS. 20A and 20B, a second interconnect-level dielectric layer 90 can be formed over the first interconnect-level dielectric layer 80, the via capacitors 100′ and the transistors 200. Second interconnect-level metal interconnect structures (96, 92, 98) can be formed in the interconnect-level dielectric layer 90. The second interconnect-level metal interconnect structures (96, 92, 98) may comprise inner electrode connection structures 96 that are formed on the inner electrode 66 of a respective via capacitor 100', outer electrode connection structures 92 that are formed on the outer electrode 62 of the via capacitors 100', and device connection metal interconnect structures 98 that are formed on a respective one of the interconnect-level metal interconnect structures 88. For example, the device connection metal interconnect structures 98 may comprise source and drain connection structures 982 and gate connection structures 985 for the field effect transistors 200.

The second interconnect-level metal interconnect structures (96, 92, 98) may comprise electrode connection via structures 92 that vertically extend through the second interconnect-level dielectric layer 90 and contact top surface segments of the horizontally-extending upper conductive plate portion of the outer electrode 62. The horizontally-extending upper conductive plate portion of the outer electrode 62 is adjoined to the top ends of the tubular vertically-extending conductive portions of the outer electrode 62.

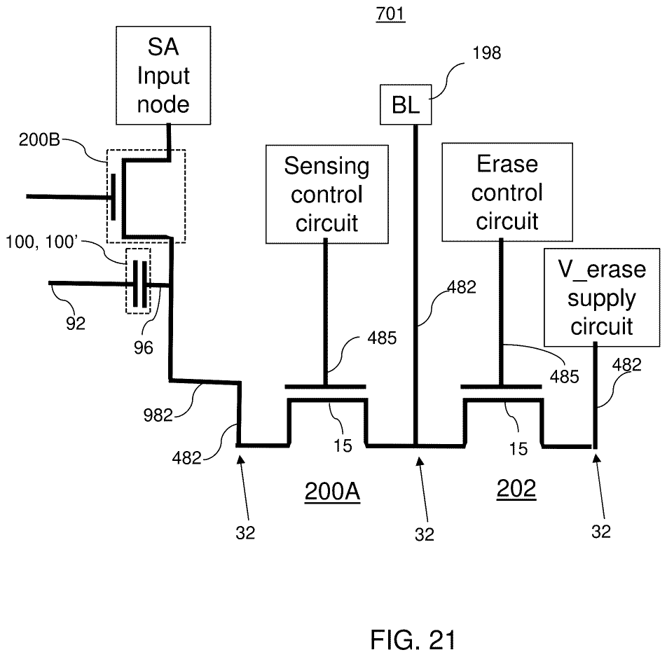

Referring to FIG. 21, a schematic circuit diagram is shown for the bit line switch circuit (e.g., sense amplifier circuit) 701 that can be formed employing the first exemplary structure of FIGS. 11A and 11B or the second exemplary structure of FIGS. 20A and 20B, according to an embodiment of the present disclosure. The field effect transistors 200 (e.g., 200A and 200B) described above may comprise sense-amplifier-connection field effect transistors of the sense amplifier circuit 701. The circuit 701 also includes erase-voltage-connection field effect transistors 202. One of a source or drain region 32 of each field effect transistor 200A can be electrically connected to a respective sense amplifier circuit input node, which is represented as SA input node, by a source or drain electrode 482 and a respective source and drain connection structure (e.g., a sense amplifier bus) 982. The second one of a source of drain region 32 which is shared between respective field effect transistor 200 and field effect transistor 202 can be electrically connected to a respective bit line 198. The other one of the source and drain region 32 of the transistors 202 can be electrically connected to an erase voltage output of an erase voltage supply circuit, which is herein referred to as V_erase supply circuit. Each gate electrode (54, 58) of the field effect transistors 200 can be electrically connected to a respective sensing control circuit. The sensing control circuit generates a signal for turning on or turning off a respective first field effect transistor 200. Specifically, when the field effect transistor 200 is turned on, a bit line 198 which is electrically connected to the field effect transistors 200 and 202 can be electrically connected to a sense amplifier input node. When the field effect transistor 200 is turned off, the bit line 198 can be electrically disconnected from the sense amplifier input node.

One of the capacitor (100, 100′) electrodes 92 or 96 may be electrically connected to the sense amplifier bus 982 which connects the sense-amplifier-connection field effect transistors 200A and 200B to the sense amplifier input node. The capacitors (100, 100′) may be located in the gap 16 between the sense-amplifier-connection field effect transistors 200A and 200B.

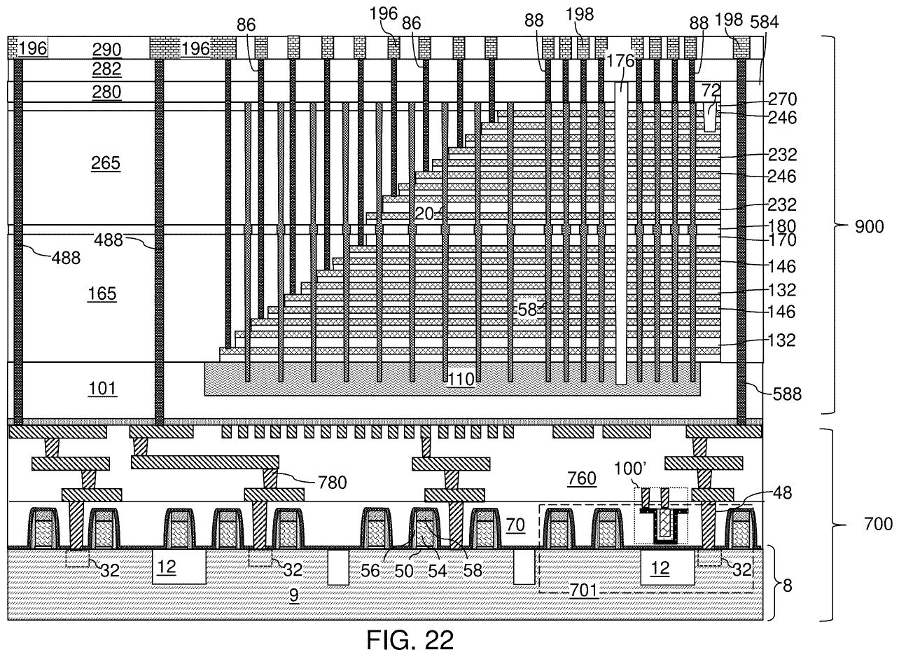

Generally, a two-dimensional array of the circuits 701 illustrated in FIG. 21 can be formed on the semiconductor substrate 9, and can be employed as a bit line switch circuit for bit lines 198 electrically connected to an array of memory elements, which may be a two-dimensional array of memory elements or a three-dimensional array of memory elements. An exemplary application of a two-dimensional array of the circuits 701 illustrated in FIG. 21 as a bit line switch circuit is illustrated in FIG. 22, which includes a three-dimensional memory device (e.g., an array of vertical NAND strings) 900 that is formed above the bit line switch circuit 701. Alternatively, the three-dimensional memory device 900 illustrated in FIG. 22 may be formed on a separate substrate (i.e., as a separate semiconductor die) and then bonded to the driver circuit 700 containing the bit line switch circuit 701 located over the substrate 9.

Generally, the semiconductor circuit (e.g., driver circuit) 700 including the bit line switch circuit 701 of FIG. 21 can be formed over the substrate 9. Lower-level dielectric material layers 760 embedding lower-level metal interconnect structures 780 are then formed over the contact-level dielectric layer 70. The memory device 900 is then either grown layer by layer over the driver circuit 700 or formed on a separate substrate and then bonded to the driver circuit 700 using mating bonding pads.

The memory device 900 includes a dielectric matrix layer 101 embedding an optional metallic plate layer 6 and a semiconductor material layer 110. A three-dimensional memory array can be formed thereupon, which may include a first-tier alternating stack of first insulating layers 132 and first electrically conductive layers 146, a first insulating cap layer 170, an inter-tier dielectric layer 180, a second-tier alternating stack of second insulating layers 232 and second electrically conductive layers 246, and a second insulating cap layer 270. The first-tier alternating stack may comprise first stepped surfaces, and a first retro-stepped dielectric material portion 165 may overlie the first stepped surfaces. The second-tier alternating stack may comprise second stepped surfaces, and a second retro-stepped dielectric material portion 265 may overlie the second stepped surfaces. Memory openings and support openings can be formed through the first-tier alternating stack and the second-tier alternating stack, and memory opening fill structures 58 can be formed in the memory openings and support pillar structures 20 can be formed in the support openings. Each of the memory opening fill structures 58 may comprise a vertical stack of memory elements (such as portions of a memory film located at levels of the first electrically conductive layers 146 and the second electrically conductive layers 246) and a vertical semiconductor channel extending through each layer within the first-tier alternating stack and the second-tier alternating stack. The memory film may comprise a charge storage layer (e.g., silicon nitride layer) located between a tunneling dielectric and a blocking dielectric. The electrically conductive layers (146, 246) comprise word lines located between source select gate electrodes and drain select gate electrodes.

Backside trenches and isolation trenches may be formed to divide the first-tier alternating stack and the second-tier alternating stack along a word line direction, which is the direction along which the first electrically conductive layers and the second electrically conductive layers laterally extend. The backside trenches may be filled with backside trench fill structures 176, and the isolation trenches may be filled with isolation structures 72. Various upper-level dielectric material layers (280, 282, 290) may be formed above the alternating stacks. Each of the memory opening fill structures 58 may include a respective drain region at a top end of a respective vertical semiconductor channel, and drain contact via structures 88 may contact the drain regions. Word line contact via structures 86 may contact the first electrically conductive layers 146 and the second electrically conductive layers 246. Bit lines 198 are electrically connected to a respective subset of the drain contact via structures 88. Word-line-connection metal interconnect structures 196 can be formed in the upper-level dielectric material layers (280, 282, 290). Connection via structures (488, 588) can be formed through the retro-stepped dielectric material potions (165, 265) or dielectric pillar structures 584 to provide vertically-extending electrical connections between lower-level metal interconnect structures 780 and upper-level metal structures such as the bit lines 198 and the word-line-connection metal interconnect structures 196. Alternatively, the memory device 900 may be formed on a separate substrate and then bonded to the driver circuit 700 upside down, such that the bit lines 198 are located between the memory opening fill structures 58 and the lower-level metal interconnect structures 780. In this case, connection via structures 588 may be omitted.

The bit lines 198 are electrically connected to the shared source or drain region 32 of a respective combination of a first field effect transistor 200A and a second field effect transistor 202, as illustrated in FIG. 21. The combination of the first field effect transistor and the second field effect transistor functions as a bit line switch that electrically connects the bit line 198 to a sensing circuit during a sensing and programming operation, and electrically connects the bit line 198 to an erase voltage supply circuit during an erase operation.

Although the foregoing refers to particular embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. All of the publications, patent applications and patents cited herein are incorporated herein by reference in their entirety.

What is claimed is:

1. A semiconductor structure, comprising:
a shallow trench isolation structure comprising a lower portion embedded in an upper portion of a semiconductor substrate and further comprising an upper portion protruding above a horizontal plane including a top surface of the semiconductor substrate;
a conductive plate located on a top surface of the shallow trench isolation structure;
a contact-level dielectric layer overlying the semiconductor substrate and the conductive plate;
a capacitor via trench vertically extending through the contact-level dielectric layer; and
a via capacitor located in the capacitor via trench and comprising an outer electrode, a capacitor dielectric, and an inner electrode, wherein the outer electrode comprises a horizontally-extending bottom conductive plate portion contacting the conductive plate, and a tubular vertically-extending conductive portion having outer sidewall segments that contact the contact-level dielectric layer.

2. The semiconductor structure of claim 1, wherein the outer electrode comprises a horizontally-extending upper conductive plate portion adjoined to a top end of the tubular vertically-extending conductive portion and having a bottom surface that contacts a segment of a top surface of the contact-level dielectric layer.

3. The semiconductor structure of claim 2, wherein the capacitor dielectric comprises:
a horizontally-extending bottom dielectric plate portion;
a tubular vertically-extending dielectric portion having outer sidewall segments that contact the tubular vertically-extending conductive portion; and
a horizontally-extending upper dielectric plate portion adjoined to the tubular vertically-extending dielectric portion and overlying the horizontally-extending upper conductive plate portion.

4. The semiconductor structure of claim 3, wherein sidewalls of the horizontally-extending upper dielectric plate portion are vertically coincident with sidewalls of the horizontally-extending upper conductive plate portion of the outer electrode.

5. The semiconductor structure of claim 2, wherein the inner electrode comprises:
a via electrode portion laterally surrounded by a tubular vertically-extending dielectric portion of the capacitor dielectric; and
a top plug electrode portion overlying the via electrode portion and having a greater lateral extent than a maximum lateral extent of the via electrode portion.

6. The semiconductor structure of claim 5, wherein:
the capacitor dielectric comprises a horizontally-extending upper dielectric plate portion overlying a horizontal plane including the top surface of the contact-level dielectric layer; and
sidewalls of the top plug electrode portion are vertically coincident with sidewalls of the horizontally-extending upper dielectric plate portion of the capacitor dielectric.

7. The semiconductor structure of claim 1, further comprising an electrode connection via structure vertically extending through the contact-level dielectric layer and contacting the conductive plate and having a top surface located above a horizontal plane including the top surface of the contact-level dielectric layer.

8. The semiconductor structure of claim 7, wherein the electrode connection via structure comprises:
an outer conductive layer having a same material composition and a same thickness as the outer electrode; and
an inner conductive fill material portion comprising a same set of at least one conductive material as the inner electrode and in direct contact with the outer conductive layer.

9. The semiconductor structure of claim 1, further comprising:
field effect transistors of a sense amplifier circuit located on the semiconductor substrate, wherein the shallow trench isolation structure is located in a gap between the field effect transistors;
a sense amplifier bus which electrically connects the field effect transistors to a sense amplifier input node, wherein one of the inner electrode and the outer electrode is electrically connected to the sense amplifier bus; and
a memory device comprising bit lines located over the field effect transistors and the via capacitor, wherein the bit lines are electrically connected to the field effect transistors.

10. The semiconductor structure of claim 9, wherein the conductive plate comprises a same material as at least a portion of gate electrodes of the field effect transistors.

11. A semiconductor structure, comprising:
a shallow trench isolation structure comprising a lower portion embedded in an upper portion of a semiconductor substrate and further comprising an upper portion protruding above a horizontal plane including a top surface of the semiconductor substrate;
field effect transistors of a sense amplifier circuit located on the semiconductor substrate, wherein the shallow trench isolation structure is located in a gap between the field effect transistors;
a contact-level dielectric layer overlying the field effect transistors and the shallow trench isolation structure;
a capacitor via trench vertically extending through the contact-level dielectric layer over or into the shallow trench isolation structure; and
a via capacitor located in the capacitor via trench and comprising an outer electrode, a capacitor dielectric, and an inner electrode, wherein one of the inner electrode and the outer electrode is electrically connected to a sense amplifier bus which electrically connects the field effect transistors to a sense amplifier input node.

12. The semiconductor structure of claim 11, further comprising a memory device comprising bit lines located over the field effect transistors and the via capacitor, wherein the bit lines are electrically connected to the field effect transistors.

13. The semiconductor structure of claim 11, wherein the outer electrode comprises a horizontally-extending bottom conductive plate portion contacting the conductive plate, and a tubular vertically-extending conductive portion having outer sidewall segments that contact the contact-level dielectric layer.

14. The semiconductor structure of claim 13, further comprising:
an interconnect-level dielectric layer overlying the contact-level dielectric layer; and
a dielectric spacer layer comprising a bottom dielectric spacer plate portion located within the capacitor via trench and underlying a bottommost surface of the outer electrode, a tubular dielectric spacer portion located in the capacitor via trench and laterally surrounding the outer electrode, and a horizontally-extending spacer layer portion overlying the interconnect-level dielectric layer.

15. The semiconductor structure of claim 14, wherein:
the capacitor via trench vertically also extends through the interconnect-level dielectric and the shallow trench isolation structure to a portion of the semiconductor substrate that underlies the shallow trench isolation structure;
the bottom spacer plate portion contacts a top surface segment of the portion of the semiconductor substrate that underlies the shallow trench isolation structure;
the outer electrode comprises a horizontally-extending upper conductive plate portion adjoined to a top end of the tubular vertically-extending conductive portion and having a bottom surface that contacts a segment of a top surface of the horizontally-extending spacer layer portion of the dielectric spacer layer;
the capacitor dielectric comprises a horizontally-extending bottom dielectric plate portion, a tubular vertically-extending dielectric portion having outer sidewall segments that contact the tubular vertically-extending conductive portion, and a horizontally-extending upper dielectric plate portion adjoined to the tubular vertically-extending dielectric portion and overlying the horizontally-extending upper conductive plate portion; and
sidewalls of the horizontally-extending upper dielectric plate portion are laterally offset inward relative to sidewalls of the horizontally-extending upper conductive plate portion of the outer electrode.

16. The semiconductor structure of claim 14, wherein:
the inner electrode comprises a via electrode portion laterally surrounded by a tubular vertically-extending dielectric portion of the capacitor dielectric, and a top plug electrode portion overlying the via electrode portion and having a greater lateral extent than a maximum lateral extent of the via electrode portion;
the capacitor dielectric comprises a horizontally-extending upper dielectric plate portion overlying a horizontal plane including a top surface of the interconnect-level dielectric layer; and
sidewalls of the top plug electrode portion are vertically coincident with sidewalls of the horizontally-extending upper dielectric plate portion of the capacitor dielectric.

17. The semiconductor structure of claim 13, further comprising:
an additional interconnect-level dielectric layer that overlies the interconnect-level dielectric layer;
an electrode connection via structure vertically extending through the additional interconnect-level dielectric layer and contacting a top surface segment of the horizontally-extending upper conductive plate portion of the outer electrode which is adjoined to a top end of the tubular vertically-extending conductive portion of the outer electrode;
contact-level metal interconnect structures comprising a respective contact-level via portion that vertically extends through the contact-level dielectric layer and contacting a respective electrical node of the semiconductor devices; and
interconnect-level metal interconnect structures comprising a respective connection-level via portion that vertically extends through the interconnect-level dielectric layer and contacting a respective one of the contact-level metal interconnect structures, wherein the interconnect-level metal interconnect structures comprising a same set of at least one conductive material as the inner electrode and is in direct contact with the interconnect-level dielectric layer.

18. A method of forming a semiconductor structure, comprising:
forming a shallow trench isolation structure in a semiconductor substrate;
forming field effect transistors on portions of the semiconductor substrate that are not covered by the shallow trench isolation structure;
forming a contact-level dielectric layer over the semiconductor substrate and the field effect transistors;
forming a capacitor via trench at least through the contact-level dielectric layer; and
forming a via capacitor in the capacitor via trench, wherein the via capacitor comprises an outer electrode, a capacitor dielectric, and an inner electrode, wherein the outer electrode comprises a horizontally-extending bottom conductive plate portion contacting the conductive plate, and a tubular vertically-extending conductive portion having outer sidewall segments that contact the contact-level dielectric layer.

19. The method of claim 18, further comprising patterning an electrically conductive layer located over the trench isolation structure to form a conductive plate on a top surface of the shallow trench isolation structure and at least portions of the gate electrodes of the field effect transistors.

20. The method of claim 18, further comprising providing a memory device comprising bit lines located over the field effect transistors and the via capacitor, wherein the bit lines are electrically connected to the field effect transistors.
